(19) United States
(12) Patent Application Publication
(10) Pub. No.: US 2024/0178371 A1
(43) Pub. Date: May 30, 2024

(54) SILICON-BASED ANODE MATERIAL WITH HIGH STABILITY AND CONDUCTIVITY FOR LITHIUM-ION BATTERIES AND PREPARATION METHOD THEREOF

(71) Applicant: Lanzhou Institute of Chemical Physics, CAS, Lanzhou City (CN)

(72) Inventors: Bin ZHANG, Lanzhou City (CN); Zhengde WANG, Lanzhou City (CN); Junyan ZHANG, Lanzhou City (CN)

(21) Appl. No.: 18/238,894

(22) Filed: Aug. 28, 2023

(30) Foreign Application Priority Data
Nov. 30, 2022 (CN) 202211511004.7

(51) Int. Cl. H01M 4/36; C23C 14/06; C23C 14/34; C23C 14/35; H01M 4/04; H01M 4/38; H01M 4/62

(52) U.S. Cl. CPC H01M 4/366; C23C 14/0605; C23C 14/345; C23C 14/35; H01M 4/0426; H01M 4/0471; H01M 4/386; H01M 4/625; H01M 2004/027

(57) ABSTRACT

Provided is a silicon-based anode material with high stability and conductivity for lithium-ion batteries, which is prepared by depositing a multilayer composite carbon coating on a surface of a silicon-based anode material for lithium-ion batteries by adjusting an alternate operation of a negative bias and a positive bias and utilizing unbalanced magnetron sputtering. Where a structure of the multilayer composite carbon coating, from a nano silicon power outward, comprises a diamond-like carbon transition layer and a high-conductivity graphite-like functional layer arranged alternately in sequence; an Sp3 structure of the diamond-like carbon transition layer has a carbon content of at least 65 at %; and an Sp2 structure of the graphite-like functional layer has a carbon content of at least 65 at %.

### CROSS REFERENCE TO RELATED APPLICATION

This patent application claims the benefit and priority of Chinese Patent Application No. 202211511004.7 filed with the China National Intellectual Property Administration on Nov. 30, 2022, the disclosure of which is incorporated by reference herein in its entirety as part of the present application.

### TECHNICAL FIELD

The present disclosure relates to the preparation of a silicon-based anode material for lithium-ion batteries, and in particular to a method for preparing a silicon-based anode material with high stability and conductivity for lithium-ion batteries, and belongs to the technical fields of composite materials and electrochemistry.

### BACKGROUND

Lithium-ion batteries exhibit great application potential in energy sources storage and utilization of many fields, such as electromobility, micro-electronic devices, and microsensors. At present, the capacity (372 mA h g⁻¹) of a commercial graphite cathode gradually cannot meet the demands of the long cruising ability of the electric automobile market. Therefore, it is urgent to develop an anode material with high power capacity for lithium-ion batteries.

Silicon (Si) has a larger theoretical capacity of 3579 mA h g⁻¹ and lower costs. Thus, it is expected to replace graphite as the next generation of anode material for lithium-ion batteries. However, silicon-based anode materials still have many problems, e.g., low intrinsic conductivity, large volume expansion/shrinkage during the charging and discharging process, easy-to-form cracks, and subsequent crushing of the electrode active substances, which causes irreversible capacity loss. The above problems seriously hinder the commercialization of silicon-based anode materials.

CN114497516A discloses a yolk-shell carbon-coated silicon composite anode material and a preparation method thereof. The method comprises: mixing and dispersing a silicon alloy powder and a carbon material under the action of an acrylonitrile-acrylic copolymer which is used as a binder to obtain a carbon material-coated silicon alloy composite powder; subjecting the composite powder to a thermal treatment in an inert atmosphere such that the binder is carbonized; adding the heat treated composite powder to a metal corrosive solution, stirring and dispersing to remove the metal in the composite powder; and filtering, washing and drying the removed composite powder in sequence, and subjecting the resulting composite powder to a thermal treatment such that organics in the composite are thoroughly carbonized to obtain the yolk-shell carbon-coated silicon composite anode material. CN115207331A discloses a silicon-based anode material with a porous core-shell structure, a preparation method thereof, and a lithium-ion battery. The method includes: mixing a mixture of a nano silicon power and lithium with a carbon source under a protection of an inert gas, subjecting the resulting mixture to a heat treatment at a temperature of 300-900° C., wherein the carbon source is one or more compound selected from the group consisting of CO₂, CS₂, CF₄, and CC₁₄. However, the carbon-coated action on the surface of the silicon-based anode material prepared by the above technical solutions is weaker. Moreover, during the preparation process, impurities are prone to be introduced. In the high-temperature process, materials are prone to polymerization and agglomeration, Energy consumption is high. Dye to the problems of the complex preparation process, long preparation time, and low yield for one time, the above technical solutions are hard to achieve the commercial and scale-up application of the silicon-based anode material.

### SUMMARY

In view of the above defects existing in the prior art, an object of the present disclosure is to provide a method for preparing a silicon-based anode material for lithium-ion batteries coated with a multilayer composite carbon coating so as to solve the prior-art problem of volume expansion and improve the conductivity and cyclic stability of the electrode material at the same time.

In the method for preparing a silicon-based anode material with high stability and conductivity for lithium-ion batteries provided by the present disclosure, a multilayer composite carbon coating is deposited on a surface of the silicon-based anode material for lithium-ion batteries by adjusting an alternate operation of a negative bias and a positive bias and utilizing unbalanced magnetron sputtering, thereby obtaining the silicon-based anode material with high stability and conductivity for lithium-ion batteries. The method includes:
(1) drying a nano silicon power, placing on a rotary frame in a vacuum coating chamber of a magnetron sputtering device, adjusting a target distance and vacuumizing the vacuum coating chamber to 10⁻⁴ Pa, switching on the rotary frame and a graphite target; where the drying is conducted in a drying oven at a temperature of 110° C. in a vacuum for 120 min;
(2) introducing argon, adjusting a working air pressure in the chamber to 1.2 Pa, connecting a negative bias to the rotary frame, and depositing a diamond-like carbon transition layer by unbalanced magnetron sputtering, where the negative bias is in a range of −80 V to −100 V, a target current is 1 A, and the diamond-like carbon transition layer has a thickness of 2 nm and an Sp3 structure with a carbon content of at least 65 at %;
(3) connecting a positive bias to the rotary frame, and depositing a graphite-like functional layer by unbalanced magnetron sputtering, where the positive bias is in a range of −80 V to −100 V, a target current is 0.8 A, and the graphite-like functional layer has a thickness of 3 nm and an Sp2 structure with a carbon content of at least 65 at %; and
(4) repeating steps (2) and (3) alternately until a target film thickness is achieved, i.e., obtaining the silicon-based anode material for lithium-ion batteries coated with a multilayer composite carbon coating. The film has a target thickness of 10 nm.

FIG. 1 shows a schematic diagram of the structure of the silicon-based anode material for lithium-ion batteries coated with a multilayer composite carbon coating according to some embodiments. The structure of the composite carbon coating, from the nano silicon power outward, comprises a diamond-like carbon transition layer and a high-conductivity graphite-like functional layer arranged alternately in sequence.

In the present disclosure, the negative bias is firstly connected to the substrate, and the diamond-like carbon transition layer is deposited by unbalanced magnetron sputtering. The negative bias could adsorb more positive ions to make the film more compact and enhance the binding force of the film. The positive bias is then connected to the substrate, and the graphite-like functional layer is deposited by unbalanced magnetron sputtering. The positive bias could adsorb more electrons to heat the changer, thus accelerating the graphitization of carbon and improving the conductivity of electrode materials. The alternately dope of diamond-like carbon transition layer and the graphite-like functional layer could ensure a higher doping amount and structural stability. Therefore, in the present disclosure, the carbon film could effectively inhibit the volume expansion during the charging and discharging process and improve the stability of the silicon-based anode material. Meanwhile, the graphite-like carbon film could effectively improve the conductivity of the anode material.

The prepared silicon-based anode material for lithium-ion batteries coated with a multilayer composite carbon coating may be prepared into a lithium-ion half cell. The lithium-ion half cell has a specific capacity of 1008.6 mA h g⁻¹ after 100 cycles in a secondary electrolyte solution (1.0M LiPF6 in EC:DEC:EMC=1:1:1 Vol %) at a current density of 500 mA g⁻¹ and a voltage of 0.1-1.5 V, showing good cyclic stability. Therefore, the silicon-based anode material for lithium-ion batteries has a broad market application prospect.

To sum up, compared with the prior art, the present disclosure has the following beneficial effects:
1. A high conductivity multilayer composite carbon coating is deposited on the surface of the silicon-based anode material for lithium-ion batteries by adjusting the alternate operation of the positive bias and negative bias and utilizing unbalanced magnetron sputtering. The alternately dope of the diamond-like carbon transition layer and the graphite-like functional layer could ensure a higher doping amount and structural stability, thus solving the problems of the conventional silicon-based anode powder, such as low intrinsic conductivity and volume expansion in the application process.
2. The method does not involve a liquid phase and a high-temperature process, which effectively avoids the introduction of impurities and the polymerization agglomeration of materials. The experiment has a highly controllable process, low pollution, and a broad market application prospect.

### BRIEF DESCRIPTION OF THE DRAWINGS

FIG. 1 shows a flow chart of the preparation of the multilayer composite carbon coating of the silicon-based anode material for lithium-ion batteries according to the present disclosure.

FIG. 2 shows a schematic diagram of the alternate change of the positive bias and negative bias during the preparation of the silicon-based anode material for lithium-ion batteries according to the present disclosure.

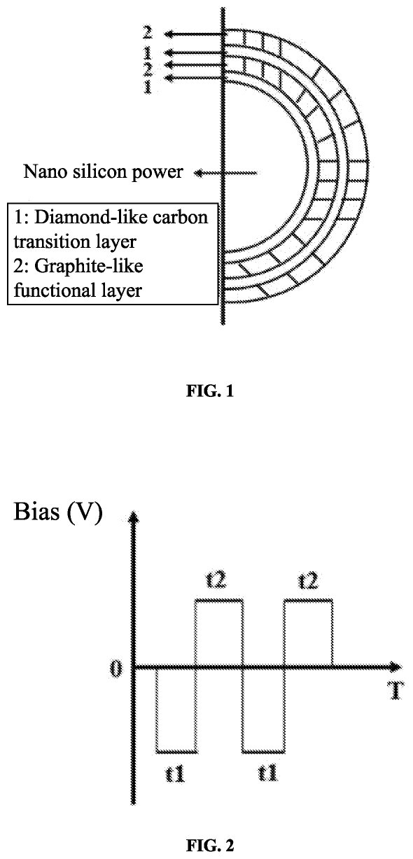

### DETAILED DESCRIPTION OF THE EMBODIMENTS

The preparation and performance of the silicon-based anode material for lithium-ion batteries provided by the present disclosure will be described in detail below with reference to specific examples.

### Example 1

(1) Experimental conditions of film deposition: 150 g of a nano silicon power dried in a vacuum at 110° C. was weighed and then placed on a rotary frame in a vacuum coating chamber of a magnetron sputtering device. A target distance of the magnetron sputtering device was adjusted. The vacuum coating chamber was vacuumized to 10⁻⁴ Pa. A rotary device of the magnetron sputtering device was switched on such that the graphite target and the rotary frame rotated at a uniform speed in opposite directions.
(2) Preparation of a diamond-like carbon film: Argon was introduced to maintain an operating pressure of the chamber at 1.2 Pa. A negative bias of −80 V was connected to the rotary frame. A diamond-like carbon film having a thickness of 2 nm was deposited at a target current of 1 A by unbalanced magnetron sputtering.
(3) Preparation of a graphite-like carbon film: The operating pressure of the chamber was maintained at 1.2 Pa. A positive bias of 80 V was connected to the rotary frame. A graphite-like carbon film having a thickness of 3 nm was deposited at a target current of 0.8 A by unbalanced magnetron sputtering.
(4) Steps (2) and (3) were repeated alternately until a film thickness reached 10 nm, and the reaction was stopped. A silicon-based anode material for lithium-ion batteries coated with a multilayer composite carbon coating was prepared.
(5) The prepared silicon-based anode material for lithium-ion batteries was prepared into a lithium-ion half cell. The lithium-ion half cell has a specific capacity of 984.2 mA h g⁻¹ after 100 cycles in a secondary electrolyte solution (1.0M LiPF6 in EC:DEC:EMC=1:1:1 Vol %) at a current density of 500 mA g⁻¹ and a voltage of 0.1-1.5 V, showing good cyclic stability.

### Example 2

(1) Experimental conditions of film deposition: 150 g of a nano silicon power dried in a vacuum at 110° C. was weighed and then placed on a rotary frame in a vacuum chamber of a magnetron sputtering device. A target distance of the magnetron sputtering device was adjusted. The vacuum coating chamber was vacuumized to 10⁻⁴ Pa. A rotary device of the magnetron sputtering device was switched on such that the graphite target and the rotary frame rotated at a uniform speed in opposite directions.
(2) Preparation of a diamond-like carbon film: Argon was introduced to maintain an operating pressure of the chamber at 1.2 Pa. A negative bias of −100 V was connected to the rotary frame. A film having a thickness of 2 nm was deposited at a target current of 1 A by unbalanced magnetron sputtering.
(3) Preparation of a graphite-like carbon film: The operating pressure of the chamber was maintained at 1.2 Pa. A positive bias of 100 V was connected to the rotary frame. A film having a thickness of 3 nm was deposited at a target current of 0.8 A by unbalanced magnetron sputtering.
(4) Steps (2) and (3) were repeated alternately until a film thickness reached 10 nm, and the reaction was stopped. A silicon-based anode material for lithium-ion batteries coated with a multilayer composite carbon coating was prepared.
(5) The prepared silicon-based anode material for lithium-ion batteries was prepared into a lithium-ion half cell. The lithium-ion half cell has a specific capacity of 1008.6 mA h g⁻¹ after 100 cycles in a secondary electrolyte solution (1.0M LiPF6 in EC:DEC:EMC=1:1:1 Vol %) at a current density of 500 mA g⁻¹ and a voltage of 0.1-1.5 V, showing good cyclic stability.

### Example 3

(1) Experimental conditions of film deposition: 150 g of a nano silicon power dried in a vacuum at 110° C. was weighed and then placed on a rotary frame in a vacuum coating chamber of a magnetron sputtering device. A target distance of the magnetron sputtering device was adjusted. The vacuum coating chamber was vacuumized to 10⁻⁴ Pa. A rotary device of the magnetron sputtering device was switched on such that the graphite target and the rotary frame rotated at a uniform speed in opposite directions.
(2) Preparation of a diamond-like carbon film: Argon was introduced to maintain an operating pressure of the chamber at 1.2 Pa. A negative bias of −90 V was connected to the rotary frame. A film having a thickness of 2 nm was deposited at a target current of 1 A by unbalanced magnetron sputtering.
(3) Preparation of a graphite-like carbon film: The operating pressure of the chamber was maintained at 1.2 Pa. A positive bias of 90 V was connected to the rotary frame. A film having a thickness of 3 nm was deposited at a target current of 0.8 A by unbalanced magnetron sputtering.
(4) Steps (2) and (3) were repeated alternately until a film thickness reached 10 nm, and the reaction was stopped. A silicon-based anode material for lithium-ion batteries coated with a multilayer composite carbon coating was prepared.
(5) The prepared silicon-based anode material for lithium-ion batteries was prepared into a lithium-ion half cell. The lithium-ion half cell has a specific capacity of 988.3 mA h g⁻¹ after 100 cycles in a secondary electrolyte solution (1.0M LiPF6 in EC:DEC:EMC=1:1:1 Vol %) at a current density of 500 mA g⁻¹ and a voltage of 0.1-1.5 V, showing good cyclic stability.

Comparative Example: An anode material for lithium-ion batteries prepared by a nano silicon power without surface coating treatment was prepared into a lithium-ion half cell. The lithium-ion half cell has a specific capacity of 306 mA h g⁻¹ after 20 cycles in a secondary electrolyte solution (1.0M LiPF6 in EC:DEC:EMC=1:1:1 Vol %) at a current density of 500 mA g⁻¹ and a voltage of 0.1-1.5 V, showing poor cyclic stability.

What is claimed is:

1. A silicon-based anode material with high stability and conductivity for lithium-ion batteries, which is prepared by depositing a multilayer composite carbon coating on a surface of a silicon-based anode material for lithium-ion batteries by adjusting an alternate operation of a negative bias and a positive bias and utilizing unbalanced magnetron sputtering.

2. The silicon-based anode material with high stability and conductivity for lithium-ion batteries of claim 1, wherein a structure of the composite carbon coating, from a nano silicon power outward, comprises a diamond-like carbon transition layer and a high-conductivity graphite-like functional layer arranged alternately in sequence, wherein the diamond-like carbon transition layer has a thickness of 2 nm and an Sp3 structure with a carbon content of at least 65 at %; and the graphite-like functional layer has a thickness of 3 nm and an Sp2 structure with a carbon content of at least 65 at %.

3. The silicon-based anode material with high stability and conductivity for lithium-ion batteries of claim 1, wherein the composite carbon coating has a thickness of 10 nm.

4. A method for preparing the silicon-based anode material with high stability and conductivity for lithium-ion batteries of claim 1, comprising:
(1) drying a nano silicon power, placing on a rotary frame in a vacuum coating chamber of a magnetron sputtering device, adjusting a target distance and vacuumizing the vacuum coating chamber to 10⁻⁴ Pa, switching on the rotary frame and a graphite target;
(2) introducing argon, adjusting a working air pressure in the chamber to 1.2 Pa, connecting a negative bias to the rotary frame, and depositing a diamond-like carbon transition layer by unbalanced magnetron sputtering, wherein the negative bias is in a range of −80 V to −100 V and a target current is 1 A;
(3) connecting a positive bias to the rotary frame, and depositing a graphite-like functional layer by unbalanced magnetron sputtering, wherein the positive bias is a range of −80 V to −100 V and a target current is 0.8 A; and
(4) repeating steps (2) and (3) alternately until a target film thickness is achieved, thereby obtaining the silicon-based anode material for lithium-ion batteries coated with a multilayer composite carbon coating.

5. The method of claim 4, wherein in step (1), the drying is conducted in a drying oven at a temperature of 110° C. in a vacuum for 120 min.

6. The method of claim 4, wherein the rotary frame for bearing the nano silicon power and the graphite target rotate at a uniform speed in opposite directions.
